(19) United States
(12) Patent Application Publication
(10) Pub. No.: US 2016/0078910 A1
(43) Pub. Date: Mar. 17, 2016

(54) SEMICONDUCTOR MEMORY DEVICE AND DRIVING METHOD THEREOF

(71) Applicant: Kabushiki Kaisha Toshiba, Minato-ku (JP)

(72) Inventor: Mitsuru SATO, Kuwana (JP)

(73) Assignee: Kabushiki Kaisha Toshiba, Minato-ku (JP)

(21) Appl. No.: 14/657,297

(22) Filed: Mar. 13, 2015

Related U.S. Application Data
(60) Provisional application No. 62/049,502, filed on Sep. 12, 2014.

(51) Int. Cl. G11C 7/12; G11C 5/02

(52) U.S. Cl. CPC G11C 7/12; G11C 5/02

(57) ABSTRACT

According to one embodiment, a driving method of a semiconductor memory device, the semiconductor memory device has a stacked body, in which a first electrode film, a second electrode film, a third electrode film are stacked in this order via insulating films, a first semiconductor pillar extending in a stacking direction of the first electrode film, the second electrode film, and the third electrode film and provided in the stacked body, and a memory film. The driving method comprises applying a first voltage to the third electrode film, the first voltage being lower than a second voltage applied to the first electrode film, in case applying a program voltage to the second electrode film, the program voltage to inject charges from the first semiconductor pillar to a portion of the memory film located between the first semiconductor pillar and the second electrode film.

### CROSS-REFERENCE TO RELATED APPLICATIONS

This application is based upon and claims the benefit of priority from U.S Provisional Patent Application 62/049,502, filed on Sep. 12, 2014; the entire contents of which are incorporated herein by reference.

### FIELD

Embodiments described herein relate generally to a semiconductor memory device and a driving method thereof

### BACKGROUND

In recent years, a semiconductor memory device in which memory cells are stacked in three-dimensional directions has been developed. In such a device, a plurality of stacked memory cells are connected through a channel to form a memory string. In case of data is written in any memory cell in the memory string, predetermined voltages are respectively applied to the memory cells to perform selective writing in the memory cells.

### BRIEF DESCRIPTION OF THE DRAWINGS

FIG. 1 is a perspective view illustrating a semiconductor memory device according to an embodiment;

FIG. 2 is a sectional view of a memory unit of the semiconductor memory device according to the embodiment taken along line A-A′ in FIG. 1;

FIGS. 3A and 3B are graph charts illustrating voltages applied to control gate electrodes in the driving method of the semiconductor memory device according to the embodiment with the voltages plotted on the abscissa and the control gate electrodes plotted on the ordinate;

FIGS. 4A and 4C are sectional views illustrating a periphery of the control gate electrodes of the semiconductor memory device according to the embodiment, FIGS. 4B and 4D are graph charts illustrating a number of electrons trapped in each charge storage films in the driving method of the semiconductor memory device according to the embodiment with a number of electrons trapped plotted on the abscissa and a charge storage film in the vicinity of the control gate electrodes plotted on the ordinate;

FIGS. 5A and 5B are graph charts illustrating voltages applied to the control gate electrodes in the driving method of the semiconductor memory device according to a comparative example with the voltages plotted on the abscissa and the control gate electrodes plotted on the ordinate; and

FIGS. 6A and 6C are sectional views illustrating a periphery of control gate electrodes of the semiconductor memory device according to a comparative example, FIGS. 6B and 6D are graph charts illustrating a number of electrons trapped in each charge storage films in the driving method of the semiconductor memory device according to a comparative example with a number of electrons trapped plotted on the abscissa and a charge storage film in the vicinity of the control gate electrodes plotted on the ordinate.

### DETAILED DESCRIPTION

In general, according to one embodiment, a driving method of a semiconductor memory device, the semiconductor memory device has a stacked body, in which a first electrode film, a second electrode film, a third electrode film are stacked in this order via insulating films, a first semiconductor pillar extending in a stacking direction of the first electrode film, the second electrode film, and the third electrode film and provided in the stacked body, and a memory film provided on a side surface of the first first semiconductor pillar and capable of charges. An angel is formed by a surface on the third electrode film side of the second electrode film and the side surface of the first semiconductor pillar being acute angle in case viewed from one direction orthogonal to the stacking direction. The driving method comprises applying a first voltage to the third electrode film, the first voltage being lower than a second voltage applied to the first electrode film, in case applying a program voltage to the second electrode film, the program voltage to inject charges from the first semiconductor pillar to a portion of the memory film located between the first semiconductor pillar and the second electrode film.

An embodiment of the invention is described below with reference to the drawings.

### Embodiment

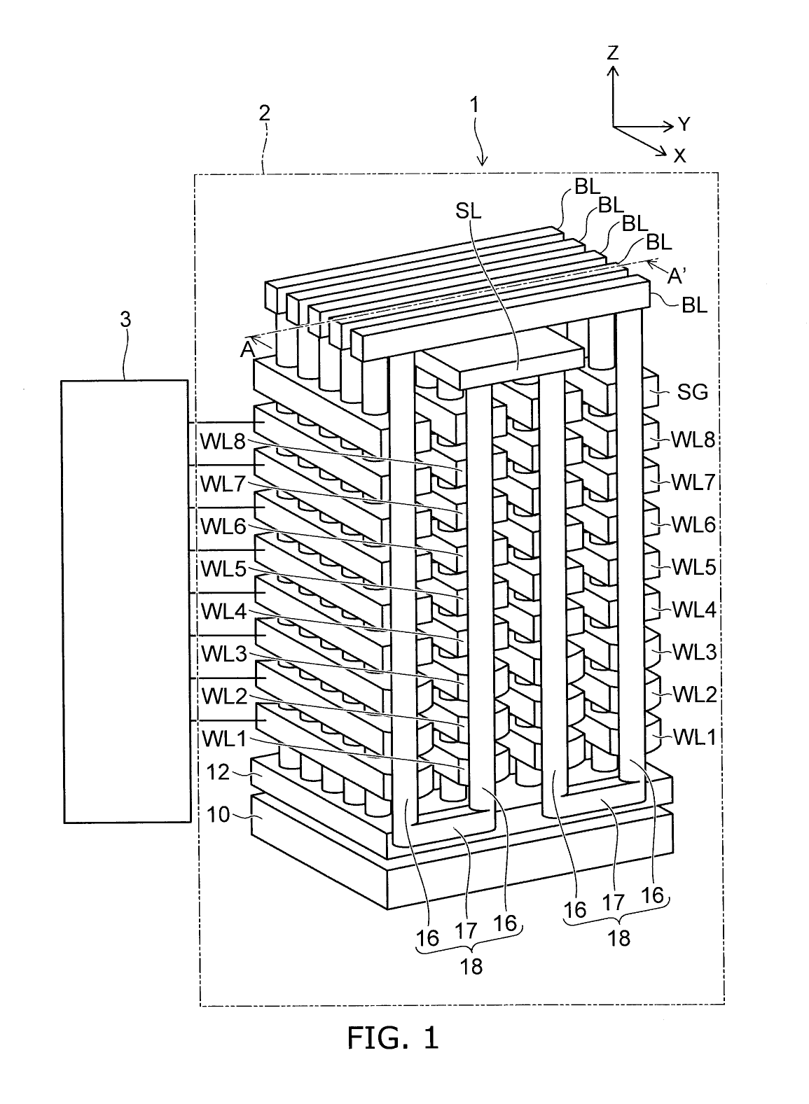

FIG. 1 is a perspective view illustrating a semiconductor memory device according to an embodiment.

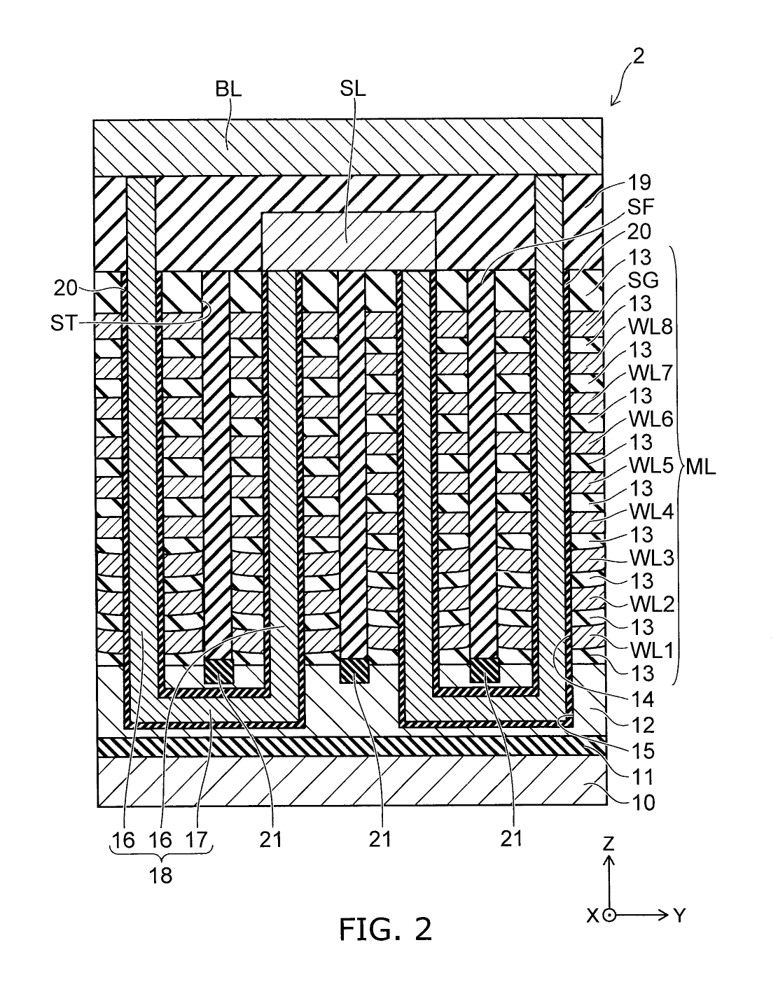

FIG. 2 is a sectional view of a driving circuit of the semiconductor memory device according to the embodiment taken along line A-A′ in FIG. 1.

As shown in FIG. 1, in a semiconductor memory device 1 according to the embodiment, a memory unit 2 and a driving circuit 3 are provided.

First, the memory unit 2 of the semiconductor memory device 1 according to the embodiment is described.

As shown in FIGS. 1 and 2, a semiconductor substrate 10 is provided in the memory unit 2.

Note that, in the memory unit 2 shown in FIG. 1, only the semiconductor substrate 10 and conductive portions are shown to clearly show the figure. Insulated portions are not shown. The driving circuit 3 shown in FIG. 1 does not reflect an actual shape and actual dimensions. A function of the driving circuit 3 is shown as a rectangular block.

In the following description, in the specification, an XYZ rectangular coordinate system is introduced for convenience of description.

In the coordinate system, two directions parallel to the major surface of the semiconductor substrate 10 shown in FIG. 1 and orthogonal to each other are represented as an X-direction and a Y-direction. A direction orthogonal to both of the X-direction and the Y-direction is represented as a Z-direction.

An insulating film 11 is provided on the semiconductor substrate 10. A back gate electrode film 12 is provided on the insulating film 11. A stacked body ML in which a plurality of insulating films 13 and a plurality of electrode films are alternately stacked is provided on the back gate electrode film 12. Slits ST are provided to divide the stacked body ML along the X-direction. In the slits ST, insulating members SF are provided. Consequently, the electrode films configuring the sacked body ML are formed as a plurality of control gate electrode films and a selection gate electrode SG. The electrode films are control gate electrodes WL1, WL2, WL3, WL4, WL5, WL6, WL7, and WL8 and the selection gate electrode SG in order from the bottom layer. Note that the number of stages of the control gate electrodes is not limited to eight.

In an upper part of the back gate electrode film 12, stopper members 21 made of metal oxide such as tantalum oxide (TaO) are provided in regions right under the insulating members SF. Silicon oxide or a metal material may be used for the stopper members 21. The stopper members 21 are provided as stoppers in forming the slits ST in the stacked body ML. As described above, the material of the stopper members 21 is, for example, metal oxide. The material of the back gate electrode film 12 is, for example, polysilicon. Therefore, in a process for manufacturing the semiconductor memory device 1, when planarization treatment such as CMP (chemical mechanical polishing) is applied to the upper surface of the back gate electrode film 12 and the upper surfaces of the stopper members 21, the upper surfaces of the stopper members 21 inevitably slightly project with respect to the upper surface of the back gate electrode film 12.

In the stacked body ML, memory holes 14 are formed to pierce through the stacked body ML in the Z-direction. Recessed sections 15 having a longitudinal direction in the Y-direction are formed on the inside of the back gate electrode film 12.

The memory holes 14 pierce through the control gate electrodes WL8, WL7, WL6, WL5, WL4, WL3, WL2, and WL1 in the respective stages and reach one end portions in the longitudinal direction of the recessed sections 15. Consequently, two memory holes 14 adjacent to each other in the Y-direction are caused to communicate with both the end portions of the same recessed section 15.

A memory film 20 is consecutively provided without being broken on the inner surfaces of the memory holes 14 and the recessed sections 15. In the memory film 20, a block insulating film made of, for example, silicon oxide, a charge storage film made of, for example, silicon nitride, and a tunnel insulating film made of, for example, silicon oxide are stacked in order from the inner surfaces of the memory holes 14. The block insulating film is a film that does not substantially feed an electric current even if a voltage is applied in a range of a driving voltage of the semiconductor memory device 1. The charge storage film is a film having an ability for retaining charges. The tunnel insulating film is a film that is usually insulative but, when a predetermined voltage within the range of the driving voltage of the semiconductor memory device 1 is applied thereto, feeds a tunnel current.

In the memory holes 14 and the recessed sections 15, a semiconductor material, for example, polysilicon doped with impurities is filled. Consequently, semiconductor pillars 16 are provided on the insides of the memory holes 14. Connecting members 17 are provided on the insides of the recessed sections 15. The shape of the semiconductor pillars 16 is a columnar shape, for example, a cylindrical shape extending in the Z-direction. The shape of the connecting members 17 is, for example, a rectangular parallelepiped shape having a longitudinal direction in the Y-direction. Consequently, a U-shaped pillar 18 is formed by two semiconductor pillars 16, which are connected via the connecting member 17, and the connecting member 17.

The stopper members 21 are located in a region right above a space between two connecting members 17 and in regions right above the centers of the connecting members 17.

Among the control gate electrodes WL1, WL2, WL3, WL4, WL5, WL6, WL7, and WL8, the control gate electrodes WL1, WL2, and WL3 in the lower layers are affected by a level difference between the upper surface of the back gate electrode film 12 and the upper surfaces of the stopper members 21 and inclined. Actually, the inclination of the control gate electrodes changes little by little from the lower layers to the upper layers. However, in the specification and the figures, for convenience of description, it is assumed that three stages in the lower layers, that is, the control gate electrodes WL1, WL2, and WL3 are inclined.

Since the control gate electrodes WL1, WL2, and WL3 are inclined, the control gate electrodes WL1, WL2, and WL3 are not orthogonal to the semiconductor pillars 16. When viewed from the X-direction, the control gate electrodes WL1, WL2, and WL3 are provided such that the upper surfaces of the control gate electrodes WL1, WL2, and WL3 and side surfaces of the semiconductor pillars 16 form an acute angle. On the other hand, the control gate electrodes WL4, WL5, WL6, WL7, and WL8 are provided to be orthogonal to the semiconductor pillars 16.

An insulating film 19 is provided on the stacked body ML.

In a lower part of the insulating film 19, a source line SL extending in the X-direction is embedded. The source line SL is connected to one of the pair of semiconductor pillars 16 configuring the U-shaped pillar 18. The source line SL is located in a region right above the space between the two connecting members 17. Ends of the source line SL are formed to be located in regions right above the semiconductor pillars 16 connected to the source line SL.

A plurality of bit lines BL extending in the Y-direction are provided on the insulating film 19. One of the pair of semiconductor pillars 16 configuring the U-shaped pillar 18 is not directly connected to the source line SL and connected to the bit line BL. The semiconductor pillar 16 connected to the bit line BL is extended to pierce through the insulating film 19.

Further, the control gate electrode films WL1, WL2, WL3, WL4, WL5, WL6, WL7, and WL8 are connected to the driving circuits 3.

The driving circuit 3 generates a program voltage (Vpgm), a first voltage (Vpass1) lower than the program voltage, and a second voltage (Vpass2) lower than the first voltage and outputs the voltages.

A driving method of the semiconductor memory device according to the embodiment is described.

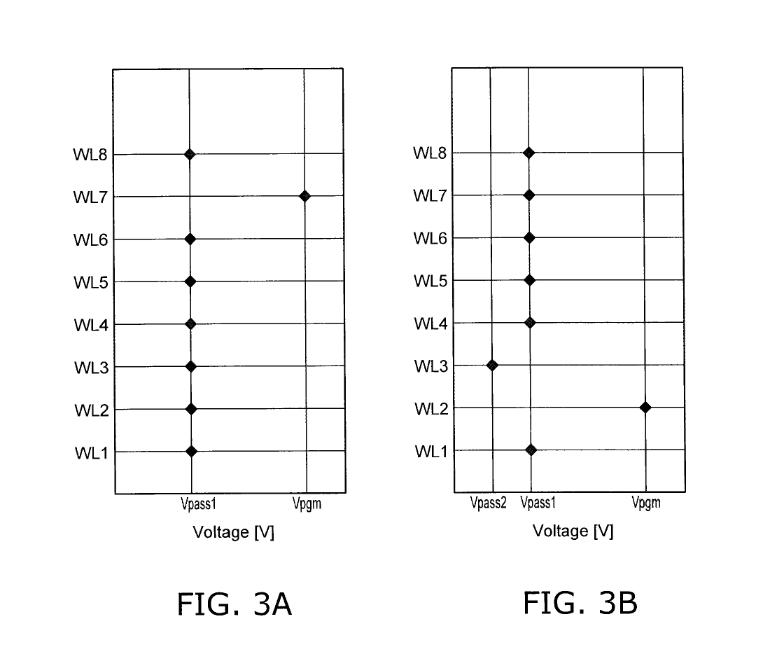

FIGS. 3A and 3B illustrate voltages applied to the control gate electrodes in the driving method of the semiconductor memory device according to the embodiment with the voltages plotted on the abscissa and the control gate electrodes plotted on the ordinate.

As shown in FIG. 3A, when the program voltage (Vpgm) is applied to the control gate electrode WL7 orthogonal to the semiconductor pillars 16, the first voltage (Vpass1) is applied to the other control gate electrodes WL1, WL2, WL3, WL4, WL5, WL6, and WL8.

As shown in FIG. 3B, when the program voltage is applied to the control gate electrode WL2, the second voltage lower than Vpass1 is applied to the control gate electrode WL3, which is a control gate electrode on a side where the control gate electrode WL2 and the side surfaces of the semiconductor pillars 16 form an acute angle when viewed from the X-direction. In this case, the first voltage is applied to the control gate electrodes WL1, WL4, WL5, WL6, WL7, and WL8 other than the control gate electrodes WL2 and WL3.

Effects of the embodiment are described.

When the program voltage is applied to the control gate electrode WL2 not orthogonal to the semiconductor pillars 16, an electric field asymmetrical on the control gate electrode WL3 side and the control gate electrode WL1 side when viewed from the control gate electrode WL2 is applied to the memory film 20. The side surfaces of the semiconductor pillars 16 and the upper surface of the control gate electrode WL2 cross to form an acute angel when viewed from the X-direction. Therefore, an electric field applied to the memory film 20 on the control gate electrode WL3 side is more intense than on the control gate electrode WL1 side.

In this case, the first voltage is applied to the control gate electrodes WL1, WL4, WL5, WL6, WL7, and WL8 and the second voltage is applied to the control gate electrode WL3. Consequently, the asymmetrical electric field due to the program voltage applied to the control gate electrode WL2 is reduced.

Consequently, when charges are injected into the charge storage film between the control gate electrode WL2 and the semiconductor pillars 16, it is possible to suppress the charges from being injected into the charge storage film on the control gate electrode WL3 side.

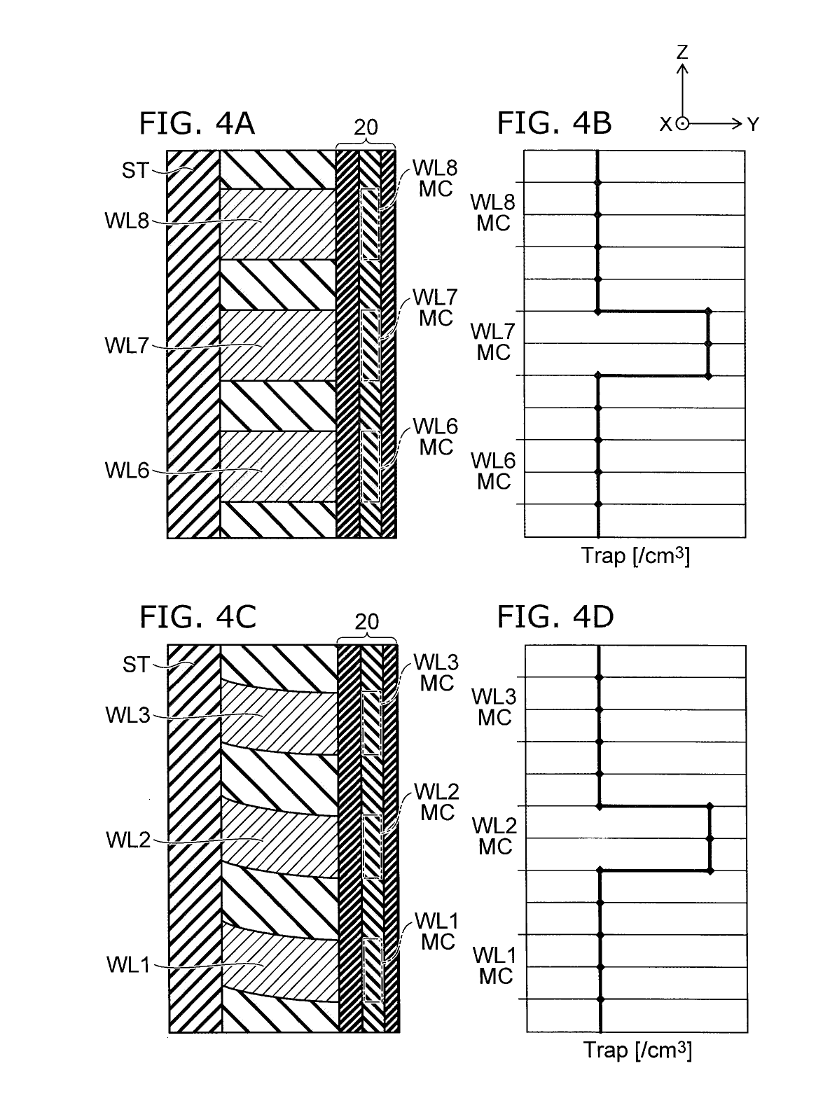

FIG. 4A is an enlarged view of the vicinity of the memory film 20 that covers the control gate electrodes WL6, WL7, and WL8 and the semiconductor pillars 16 shown in FIG. 2. In FIG. 4B, the number of electrons trapped when the voltage shown in FIG. 3A is applied is plotted on the abscissa. Regions of the charge storage film of the memory film 20 contiguous to the control gate electrodes WL6, WL7, and WL8 are shown on the ordinate.

In FIG. 4A, charge storage regions WL6MC, WL7MC, and WL8MC of the charge storage film corresponding to the control gate electrodes WL6, WL7, and WL8 are shown.

As shown in FIG. 4A, the control gate electrodes WL6, WL7, and WL8 orthogonally cross the memory film 20.

In this case, as shown in FIG. 4B, when the program voltage is applied to the control gate electrode WL7, electrons are selectively trapped in the charge storage region WL7MC.

FIG. 4C is an enlarged view in the vicinity of the memory film 20 that covers the control gate electrodes WL1, WL2, WL3 and the semiconductor pillars 16 shown in FIG. 2. In FIG. 4D, the number of electrons trapped when the voltage shown in FIG. 3B is applied is plotted on the abscissa. Regions of the charge storage film of the memory film 20 contiguous to the control gate electrodes WL1, WL2, and WL3 are shown on the ordinate.

In FIG. 4C, charge storage regions WL1MC, WL2MC, and WL3MC of the charge storage film corresponding to the control gate electrodes WL1, WL2, and WL3 are shown.

In this case, as shown in FIG. 4D, when the program voltage is applied to the control gate electrode WL2, since the second voltage Vpass2 lower than voltages applied to the other control gate electrodes is applied to the control gate electrode WL3, charges are not stored in a portion between the charge storage region WL2MC and the charge storage region WL3MC in the charge storage film. Electrons are also selectively trapped in the charge storage region WL2MC.

In this way, according to the embodiment, it is possible to selectively feed electrons to any memory cell even in a place where the semiconductor pillars 16 and the control gate electrodes are not orthogonal.

### Comparative Example

A comparative example is described.

The configuration of the memory unit 2 of a semiconductor memory device according to the comparative example is the same as the configuration of the memory unit 2 of the semiconductor memory device according to the embodiment. A driving circuit in the comparative example generates and outputs the program voltage and the first voltage. On the other hand, the driving circuit in the comparative example does not generate the second voltage.

The driving method of the semiconductor memory device according to the comparative example is described.

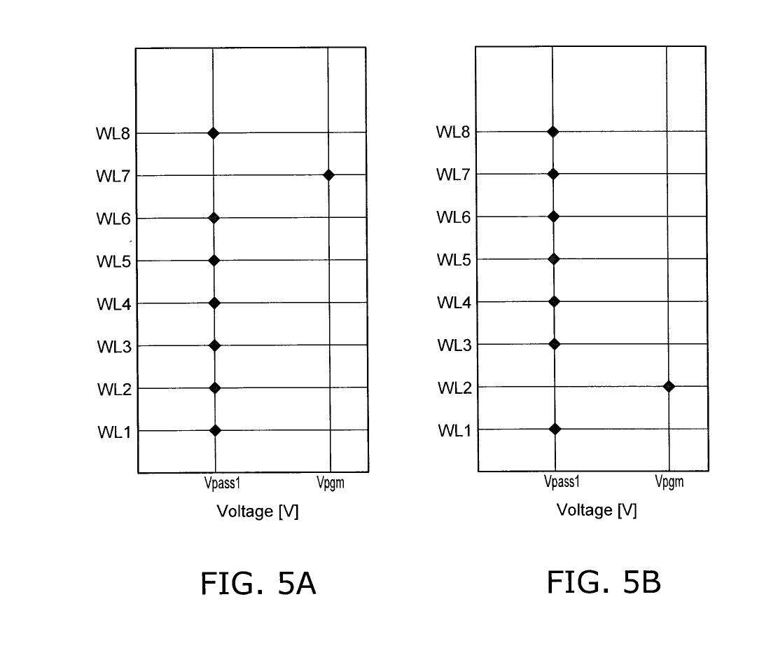

In FIGS. 5A and 5B, applied voltages are plotted on the abscissa and control gate electrodes are illustrated on the ordinate.

As shown in FIG. 5A, when the program voltage is applied to the control gate electrode WL7 orthogonal to the semiconductor pillars 16, the first voltage is applied to the other control gate electrodes WL1, WL2, WL3, WL4, WL5, WL6, and WL8.

As shown in FIG. 5B, when the program voltage is applied to the control gate electrode WL2 that crosses the side surfaces of the semiconductor pillars 16 and the upper surface of the control gate electrode WL2 to form an acute angle when viewed from the X-direction, the first voltage is also applied to the control gate electrodes WL1, WL3, WL4, WL5, WL6, WL7, and WL8 other than the control gate electrode WL2.

Operations in the comparative example are described.

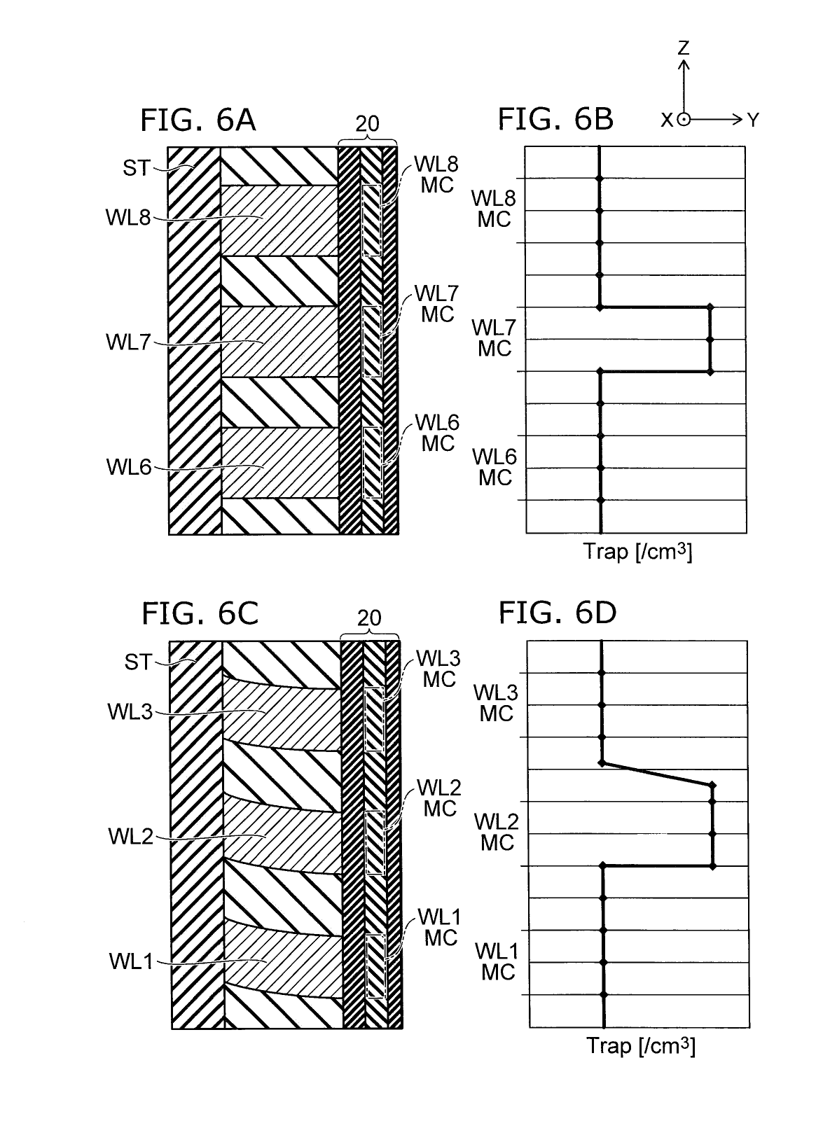

FIG. 6A is an enlarged view of the vicinity of the memory film 20 that covers the control gate electrodes WL6, WL7, and WL8 and the semiconductor pillars 16 shown in FIG. 2. In FIG. 6B, the number of electrons trapped when the voltages shown in FIG. 5A are applied is plotted on the abscissa and the charge storage film of the memory film 20 contiguous to regions of the control gate electrodes WL6, WL7, and WL8 is shown on the ordinate.

As shown in FIG. 6A, in the charge storage film corresponding to the control gate electrodes WL6, WL7, and WL8, the charge storage regions WL6MC, WL7MC, and WL8MC are present.

As shown in FIG. 6B, when the voltages shown in FIG. 5A are applied to the control gate electrodes, electrons are selectively trapped in the charge storage region WL7MC corresponding to the control gate electrode WL7 to which the program voltage is applied.

FIG. 6C is an enlarged view of the vicinity of the memory film 20 that covers the control gate electrodes WL1, WL2, and WL3 and the semiconductor pillars 16 shown in FIG. 2. In FIG. 6D, the number of electrons trapped when the voltages shown in FIG. 5B are applied is plotted on the abscissa and the charge storage film of the memory film 20 contiguous to regions of the control gate electrodes WL1, WL2, and WL3 is shown on the ordinate.

In FIG. 6C, the charge storage regions WL1MC, WL2MC, and WL3MC of the charge storage film corresponding to the control gate electrodes WL1, WL2, and WL3 are shown.

As shown in FIG. 6C, the control gate electrodes WL1, WL2, and WL3 incline to cross the memory film 20. When viewed from the X-direction, the upper surfaces of the control gate electrodes WL1, WL2, and WL3 form an acute angle with the side surfaces of the semiconductor pillars 16 and the lower surfaces of the control gate electrodes WL1, WL2, and WL3 form an obtuse angle with the side surfaces of the semiconductor pillars 16.

Consequently, for example, when the voltages shown in FIG. 5B are applied to the control gate electrodes from WL1 to WL8, the memory film 20 on the upper surface side of the control gate electrode WL2 is more affected by an electric field than the memory film 20 on the lower surface side of the control gate electrode WL2. In this case, as shown in FIG. 6D, because of the influence of the electric field, electrons are trapped between the charge storage region WL2MC and the charge storage region WL3MC besides the charge storage region WL2MC corresponding to the control gate electrode WL2 to which the program voltage is applied. Usually, the memory film 20 is caused to operate by reducing the resistance of a tunnel insulating film portion of the memory film 20 with a seepage electric field from the control gate electrodes. Therefore, when electrons are trapped in the memory film 20 between the control gate electrode WL2 and the control gate electrode WL3, the effect of the reduction in the resistance of the tunnel insulating film by the seepage electric field decreases. When a flowing electric current decreases or in order to perform writing, it is requested to apply a high voltage to the control gate electrodes. Occurrence of erroneous writing in a charge storage region other than a target charge storage region is also anticipated.

According to the embodiments described above, it is possible to realize a writing method of more accurate data in a stacked memory cell and a driving circuit for writing data in the stacked memory cell.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A driving method of a semiconductor memory device, the semiconductor memory device having a stacked body, in which a first electrode film, a second electrode film, a third electrode film are stacked in this order via insulating films, a first semiconductor pillar extending in a stacking direction of the first electrode film, the second electrode film, and the third electrode film and provided in the stacked body, and a memory film provided on a side surface of the first semiconductor pillar and capable of charges, an angel formed by a surface on the third electrode film side of the second electrode film and the side surface of the first semiconductor pillar being acute angle in case viewed from one direction orthogonal to the stacking direction,
the driving method comprising applying a first voltage to the third electrode film, the first voltage being lower than a second voltage applied to the first electrode film, in case applying a program voltage to the second electrode film to inject charges from the first semiconductor pillar to a portion of the memory film located between the first semiconductor pillar and the second electrode film.

2. The method according to claim 1, wherein
the semiconductor memory device further has a semiconductor substrate, and
the first electrode film is disposed on between the semiconductor substrate and the second electrode film.

3. The method according to claim 2, wherein the semiconductor memory device further has an insulating member configured to extend in the stacking direction and divide the stacked body and a stopper member provided between the semiconductor substrate and the insulating member.

4. The method according to claim 1, wherein the semiconductor memory device further has a second semiconductor pillar extending in a stacking direction of the first electrode film, a semiconductor substrate, a back gate electrode film provided between the semiconductor substrate and the stacked body, a connecting member provided in the back gate electrode film and configured to connect the first semiconductor pillar and the second semiconductor pillar, a bit line connected to an upper end of the first semiconductor pillar, and a source line connected to an upper end of the second semiconductor pillar.

5. The method according to claim 1, wherein, in case viewed from one direction orthogonal to the stacking direction, an angle formed by a surface on the second electrode film side in the first electrode film and the side surface of the first semiconductor pillar is smaller than the angle formed by the surface on the third electrode film side in the second electrode film and the side surface of the first semiconductor pillar.

6. The method according to claim 5, wherein
the semiconductor memory device further has a fourth electrode film disposed above the third electrode film, and
in case viewed from one direction orthogonal to the stacking direction, the angle formed by the surface on the third electrode film side in the second electrode film and the side surface of the first semiconductor pillar is smaller than an angle formed by a surface on the fourth electrode film side in the third electrode film and the side surface of the first semiconductor pillar.

7. The method according to claim 1, wherein
the semiconductor memory device further has a fourth electrode film disposed above the third electrode film, and
the fourth electrode film is orthogonal to the first semiconductor pillar.

8. The method according to claim 7, wherein, in case the program voltage is applied to the second electrode film, a voltage applied to the third electrode film is lower than a voltage applied to the forth electrode film.

9. A semiconductor memory device comprising:
a stacked body, in which a first electrode film, a second electrode film, a third electrode film are stacked in this order:
a first semiconductor pillar configured to extend in a stacking direction of the first electrode film, the second electrode film, and the third electrode film and provided in the stacked body;
a memory film provided on a side surface of the first semiconductor pillar and capable of charges; and
an angel formed by a surface on the third electrode film side in the second electrode film and the side surface of the first semiconductor pillar being acute angle in case viewed from one direction orthogonal to the stacking direction, and
a circuit configured to apply a first voltage to the third electrode film, the first voltage being lower than a second voltage applied to the first electrode film, in case applying a program voltage to the second electrode film to inject charges from the first semiconductor pillar to a portion of the memory film located between the first semiconductor pillar and the second electrode film.

10. The device according to claim 9, further comprising a semiconductor substrate, wherein
the first electrode film is disposed on between the semiconductor substrate and the second electrode film.

11. The device according to claim 10, further comprising:
an insulating member configured to extend in the stacking direction and divide the stacked body; and
a stopper member provided between the semiconductor substrate and the insulating member.

12. The device according to claim 9, further comprising:
a semiconductor substrate:
a second semiconductor pillar extending in a stacking direction of the first electrode film;
a back gate electrode film provided between the semiconductor substrate and the stacked body;
a connecting member provided in the back gate electrode film and configured to connect the first semiconductor pillar and the second semiconductor pillar;
a bit line connected to an upper end of the first semiconductor pillar; and
a source line connected to an upper end of the second semiconductor pillar.

13. The device according to claim 9, wherein, in case viewed from one direction orthogonal to the stacking direction, an angle formed by a surface on the second electrode film side in the first electrode film and the side surface of the first semiconductor pillar is smaller than the angle formed by the surface on the third electrode film side in the second electrode film and the side surface of the first semiconductor pillar.

14. The device according to claim 13, further comprising a fourth electrode film disposed above the third electrode film, wherein
in case viewed from one direction orthogonal to the stacking direction, the angle formed by the surface on the third electrode film side in the second electrode film and the side surface of the first semiconductor pillar is smaller than an angle formed by a surface on the fourth electrode film side in the third electrode film and the side surface of the first semiconductor pillar.

15. The device according to claim 9, further comprising a fourth electrode film disposed above the third electrode film, wherein
the fourth electrode film is orthogonal to the first semiconductor pillar.

16. The device according to claim 9, wherein
in case applying the program voltage to the second electrode film, the circuit applies the third voltage to the fourth electrode film, and
the first voltage applied to the third electrode film is lower than the third voltage applied to the forth electrode film.
